(19) United States
(12) Patent Application Publication
(10) Pub. No.: US 2024/0224710 A1
(43) Pub. Date: Jul. 4, 2024

(54) DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventors: Jiexin ZHENG, Shenzhen (CN); Wei LU, Shenzhen (CN)

(73) Assignee: Shenzhen China Star Optoelectronics Semiconductor Display Technology Co., Ltd., Shenzhen (CN)

(21) Appl. No.: 18/533,288

(22) Filed: Dec. 8, 2023

(30) Foreign Application Priority Data
Dec. 30, 2022 (CN) 202211739505.0

(51) Int. Cl. H10K 59/80; H10K 59/12; H10K 59/122

(52) U.S. Cl. CPC H10K 59/80522; H10K 59/1201; H10K 59/122; H10K 59/80517; H10K 59/80523

(57) ABSTRACT

A display panel and a manufacturing method thereof are provided. The display panel includes a substrate, and an electrode layer, an antioxidant metal layer, an organic layer and a cathode layer sequentially disposed on the substrate. The electrode layer includes an auxiliary electrode including stacked first and second auxiliary sub-electrodes, and an edge of the second auxiliary sub-electrode protrudes laterally relative to that of the first auxiliary sub-electrode. The antioxidant metal layer is bonded to a side surface of the first auxiliary sub-electrode and a side of the second auxiliary sub-electrode facing towards the substrate. The organic layer includes a first organic portion on the second auxiliary sub-electrode, and a second organic portion spaced therefrom and on a side of the auxiliary electrode. The cathode layer is disposed on first and second organic portions, and electrically connected to side surfaces of the second auxiliary sub-electrode and the antioxidant metal layer.

### CROSS-REFERENCE TO RELATED APPLICATION

This application claims priority to Chinese Patent Application No. 202211739505.0, filed on Dec. 30, 2022, the disclosure of which is incorporated herein by reference in its entirety.

### TECHNICAL FIELD

The present disclosure relates to the field of display technologies, and in particular, to a display panel and a manufacturing method thereof.

### BACKGROUND

In the panel display industry, an AMOLED display screen has higher color saturation and lower energy consumption than an LCD display screen. With the diversification, large screen size and high quality of customer demands, panels are developing towards larger sizes and higher resolutions. However, with the increase of panel size, some problems that are not prominent for small and medium-sized panels are gradually exposed, among which a more influential problem is that brightness uniformity of a panel gradually deteriorates with the increase of size.

One of reasons for the deterioration of brightness uniformity of the panel is that OLED devices are current-driven devices. According to the formula U=I*R, there are different VDD/VSS voltage drops (also known as IR drop effect) at different positions when the panel is lit. The IR drop effect will make a pixel brightness be relatively lower, resulting in uneven panel brightness.

For the uneven panel brightness caused by IR drop, a method usually is used is to add an auxiliary cathode line. Referring to FIG. 1, an auxiliary cathode line 2′ is added among a plurality of data lines 1′, a cathode layer and the auxiliary cathode line 2′ are connected together, so as to use the principle of reducing a resistance value through parallel connection of resistors to improve the uneven panel brightness caused by IR drop. Referring to FIG. 2, an auxiliary electrode 3′ and an anode 4′ are arranged at the same layer, the auxiliary electrode 3′ is connected to the auxiliary cathode line 2′ through a via, and the cathode layer 5′ is directly connected with the auxiliary electrode 3′ at a location of a contact hole 6′. Ideally, an organic layer 7′ of an OLED is deposited only in a pixel light-emitting region (i.e., above the anode 4′), and is not deposited at the location of the contact hole 6′, and when the cathode layer 5′ is disposed wholly to cover the entire top surface, it is directly lapped with the auxiliary electrode 3′ at the location of the contact hole 6′.

Referring to FIG. 3, in order to make the auxiliary electrode 3′ be directly lapped with the cathode layer 5′, a pixel definition layer 8′ does not cover the auxiliary electrode 3′, so that an edge of the auxiliary electrode 3′ is exposed, while the organic layer 7′ of the OLED is naturally broken/fractured at the edge of the auxiliary electrode 3′ during film formation, and finally the cathode layer 5′ when is arranged wholly to cover the entire top surface can be directly lapped with the auxiliary electrode 3′ at the broken position of the organic layer 7′. As illustrated in FIG. 3, the auxiliary electrode 3′ and the anode 4′ are arranged at the same layer, and the auxiliary electrode 3′ and the anode 4′ are made of the same material, i.e., are composed of three layers of electrically-conductive materials. In particular, an intermediate reflective layer 9′ is an ANCL alloy containing aluminum (Al), and a top layer may be an ITO or WOx transparent electrically-conductive layer 10′. After the auxiliary electrode 3′ is etched, the intermediate reflective layer 9′ will be inwardly recessed at an edge of the electrode. The organic layer 7′ is broken/fractured at the edge of the transparent electrically-conductive layer 10′ of the top layer and exposes a lateral side surface of the intermediate reflective layer 9′ when the organic layer 7′ is formed, and finally when the cathode layer 5′ is formed, it is lapped with the lateral side surface of the intermediate reflective layer 9′. However, since the edge of the intermediate reflective layer 9′ made of the ANCL alloy containing Al is oxidized after being exposed, so that the cathode layer 5′ and the auxiliary electrode 3′ are lapped together by a metal oxide, resulting in a large lapping resistance between the cathode layer 5′ and the auxiliary electrode 3′, which fails to achieve the purpose of improving the IR drop effect.

### SUMMARY

The present disclosure provides a display panel and a manufacturing method thereof, by means of an antioxidant metal layer, the cathode layer and the lateral side surface of the auxiliary electrode can form an effective lapping, so that the phenomenon that the lapping resistance of the cathode layer with the auxiliary electrode is excessively large can be avoided, and improvement effect of the IR drop for the display panel can be ensured.

Specifically, a display panel according to an embodiment of the present disclosure includes:

a substrate, including a sub-pixel region and an auxiliary electrode region arranged at intervals;

an electrode layer, disposed on the substrate and including an auxiliary electrode located in the auxiliary electrode region, wherein the auxiliary electrode includes a first auxiliary sub-electrode and a second auxiliary sub-electrode sequentially arranged on the substrate, and an edge of the second auxiliary sub-electrode protrudes laterally relative to an edge of the first auxiliary sub-electrode;

an antioxidant metal layer, bonded to a side surface of the first auxiliary sub-electrode and bonded to a side of the second auxiliary sub-electrode facing towards the substrate, wherein an antioxidant capacity of the antioxidant metal layer is greater than an antioxidant capacity of the first auxiliary sub-electrode;

an organic layer, disposed on the substrate and the electrode layer and including a first organic portion on the second auxiliary sub-electrode, and a second organic portion spaced from the first organic portion and on a side of the auxiliary electrode; wherein a thickness of the organic layer is less than a thickness of the first auxiliary sub-electrode; and

a cathode layer, disposed on the first organic portion and the second organic portion, and electrically connected to a side surface of the second auxiliary sub-electrode and a side surface of the antioxidant metal layer.

In an embodiment, the edge of the second auxiliary sub-electrode is aligned with an edge of the antioxidant metal layer, or the edge of the second auxiliary sub-electrode protrudes laterally relative to the edge of the antioxidant metal layer.

In an embodiment, a material of the antioxidant metal layer includes one or more of titanium, silver and molybdenum.

In an embodiment, a material of the first auxiliary sub-electrode includes a metal or alloy containing aluminum element, and a material of the second auxiliary sub-electrode includes indium tin oxide or a tungsten oxide.

In an embodiment, the auxiliary electrode further includes a third auxiliary sub-electrode located between the substrate and the first auxiliary sub-electrode, an edge of the third auxiliary sub-electrode protrudes laterally relative to the edge of the first auxiliary sub-electrode, the antioxidant metal layer is arranged between the second auxiliary sub-electrode and the third auxiliary sub-electrode, and the second organic portion at least covers a side surface of the third auxiliary sub-electrode.

In an embodiment, a material of the third auxiliary sub-electrode includes any one of molybdenum-titanium-nickel (MoTiNi) alloy, molybdenum-titanium (MoTi) alloy, and indium tin oxide.

In an embodiment, the electrode layer further includes an anode located in the sub-pixel region; the anode includes a first sub-anode and a second sub-anode sequentially disposed on the substrate; and an edge of the second sub-anode protrudes laterally relative to an edge of the first sub-anode;

the first sub-anode and the first auxiliary sub-electrode are arranged at a same layer and are made of a same material, the second sub-anode and the second auxiliary sub-electrode are arranged at a same layer and are made of a same material, and the second organic portion extends onto the second sub-anode; and

the antioxidant metal layer is bonded to a side surface of the first sub-anode and bonded to a side of the second sub-anode facing towards the substrate.

In an embodiment, the display panel further includes a pixel definition layer disposed on the electrode layer, and the organic layer and the cathode layer are sequentially disposed overlying the pixel definition layer; the pixel definition layer includes a main portion, and a first opening and a second opening penetrating through the main portion; the first opening is disposed corresponding to the auxiliary electrode region, and the second opening is disposed corresponding to the sub-pixel region; and

the auxiliary electrode is located in the first opening, a spacing between the main portion and a side surface of the auxiliary electrode as well as the side surface of the antioxidant metal layer is greater than 0, the anode is located in the second opening, and the main portion at least covers a side surface of the anode.

A manufacturing method of a display panel according to an embodiment of the present disclosure includes the following steps:

providing a substrate, wherein the substrate includes a sub-pixel region and an auxiliary electrode region arranged at intervals;

forming an electrode layer on the substrate, wherein the electrode layer includes an auxiliary electrode located in the auxiliary electrode region, the auxiliary electrode includes a first auxiliary sub-electrode and a second auxiliary sub-electrode sequentially disposed on the substrate, and an edge of the second auxiliary sub-electrode protrudes laterally relative to an edge of the first auxiliary sub-electrode;

forming an antioxidant metal layer, wherein the antioxidant metal layer is bonded to a side surface of the first auxiliary sub-electrode and bonded to a side of the second auxiliary sub-electrode facing towards the substrate, and an antioxidant capacity of the antioxidant metal layer is greater than an antioxidant capacity of the first auxiliary sub-electrode;

forming an organic layer covering the substrate and the electrode layer, wherein the organic layer includes a first organic portion on the second auxiliary sub-electrode, and a second organic portion spaced from the first organic portion and disposed on the substrate; and a thickness of the organic layer is less than a thickness of the first auxiliary sub-electrode; and

forming a cathode layer, wherein the cathode layer is disposed overlying the first organic portion and the second organic portion, and electrically connected to a side surface of the second auxiliary sub-electrode and a side surface of the antioxidant metal layer.

In an embodiment, the step of forming an antioxidant metal layer includes the following sub-steps:

covering with an antioxidant metal film wholly on the substrate formed with the electrode layer, wherein the antioxidant metal film covers the side surface of the first auxiliary sub-electrode; and

etching the antioxidant metal film wholly to form the antioxidant metal layer located on a side of the second auxiliary sub-electrode facing towards the substrate.

In an embodiment, the edge of the second auxiliary sub-electrode is aligned with an edge of the antioxidant metal layer, or the edge of the second auxiliary sub-electrode protrudes laterally relative to the edge of the antioxidant metal layer.

In an embodiment, a material of the antioxidant metal layer comprises one or more of titanium, silver and molybdenum.

In an embodiment, a material of the first auxiliary sub-electrode comprises a metal or alloy that contains aluminum element, and a material of the second auxiliary sub-electrode

In an embodiment, the auxiliary electrode further comprises a third auxiliary sub-electrode located between the substrate and the first auxiliary sub-electrode, an edge of the third auxiliary sub-electrode protrudes laterally relative to the edge of the first auxiliary sub-electrode, the antioxidant metal layer is arranged between the second auxiliary sub-electrode and the third auxiliary sub-electrode, and the second organic portion at least covers a side surface of the third auxiliary sub-electrode.

The present disclosure provides a display panel, comprising:

a substrate, comprising a sub-pixel region and an auxiliary electrode region arranged at intervals;

an electrode layer, disposed on the substrate and comprising an auxiliary electrode located in the auxiliary electrode region, wherein the auxiliary electrode comprises a first auxiliary sub-electrode and a second auxiliary sub-electrode sequentially arranged on the substrate, and an edge of the second auxiliary sub-electrode protrudes laterally relative to an edge of the first auxiliary sub-electrode;

an antioxidant metal layer, bonded to a side surface of the first auxiliary sub-electrode and bonded to a side of the second auxiliary sub-electrode facing towards the substrate, wherein an antioxidant capacity of the antioxidant metal layer is greater than an antioxidant capacity of the first auxiliary sub-electrode;

an organic layer, disposed on the substrate and the electrode layer, and comprising a first organic portion on the second auxiliary sub-electrode, and a second organic portion spaced from the first organic portion and on a side of the auxiliary electrode; wherein a thickness of the organic layer is less than a thickness of the first auxiliary sub-electrode; and

a cathode layer, disposed on the first organic portion and the second organic portion, and electrically connected to a side surface of the second auxiliary sub-electrode and a side surface of the antioxidant metal layer;

wherein the edge of the second auxiliary sub-electrode is aligned with an edge of the antioxidant metal layer, or the edge of the second auxiliary sub-electrode protrudes laterally relative to the edge of the antioxidant metal layer;

wherein the auxiliary electrode further comprises a third auxiliary sub-electrode located between the substrate and the first auxiliary sub-electrode, an edge of the third auxiliary sub-electrode protrudes laterally relative to the edge of the first auxiliary sub-electrode, the antioxidant metal layer is arranged between the second auxiliary sub-electrode and the third auxiliary sub-electrode, and the second organic portion at least covers a side surface of the third auxiliary sub-electrode.

In an embodiment, a material of the antioxidant metal layer comprises one or more of titanium, silver and molybdenum.

In an embodiment, a material of the first auxiliary sub-electrode comprises a metal or alloy that contains aluminum element, and a material of the second auxiliary sub-electrode comprises indium tin oxide or a tungsten oxide.

In an embodiment, a material of the third auxiliary sub-electrode comprises any one of molybdenum-titanium-nickel (MoTiNi) alloy, molybdenum-titanium (MoTi) alloy, and indium tin oxide.

In an embodiment, the electrode layer further comprises an anode located in the sub-pixel region; the anode comprises a first sub-anode and a second sub-anode sequentially disposed on the substrate; and an edge of the second sub-anode protrudes laterally relative to an edge of the first sub-anode;

wherein the first sub-anode and the first auxiliary sub-electrode are arranged at a same layer and are made of a same material, the second sub-anode and the second auxiliary sub-electrode are arranged at a same layer and are made of a same material, and the second organic portion extends onto the second sub-anode;

wherein the antioxidant metal layer is bonded to a side surface of the first sub-anode and bonded to a side of the second sub-anode facing towards the substrate.

In an embodiment, the display panel further comprises a pixel definition layer disposed on the electrode layer, and the organic layer and the cathode layer are sequentially disposed overlying the pixel definition layer; the pixel definition layer comprises a main portion, and a first opening and a second opening penetrating through the main portion; the first opening is disposed corresponding to the auxiliary electrode region, and the second opening is disposed corresponding to the sub-pixel region;

wherein the auxiliary electrode is located in the first opening, a spacing between the main portion and a side surface of the auxiliary electrode as well as the side surface of the antioxidant metal layer is greater than 0, the anode is located in the second opening, and the main portion at least covers a side surface of the anode.

For the display panel and the manufacturing method thereof according to the embodiments of the present disclosure, the side surface of the first auxiliary sub-electrode is formed with the antioxidant metal layer, which can effectively protect the side surface of the first auxiliary sub-electrode and prevent the side surface of the first auxiliary sub-electrode from exposure and thus being oxidized, so that the cathode layer can be directly lapped with the side surface of the antioxidant metal layer and the side surface of the second auxiliary sub-electrode. That is, the cathode layer and the side surface of the auxiliary electrode can form an effective lapping, so that large lapping resistance of the cathode layer and the auxiliary electrode can be avoided, and the improvement effect of IR drop for the display panel is ensured consequently.

### BRIEF DESCRIPTION OF THE DRAWINGS

Detailed descriptions of specific embodiments of the present disclosure will be given below with reference to the accompanying drawings, and thus technical solutions and other beneficial effects of the present disclosure will be apparent.

FIG. 1 is a schematic structural view of an exemplary pixel unit in the prior art.

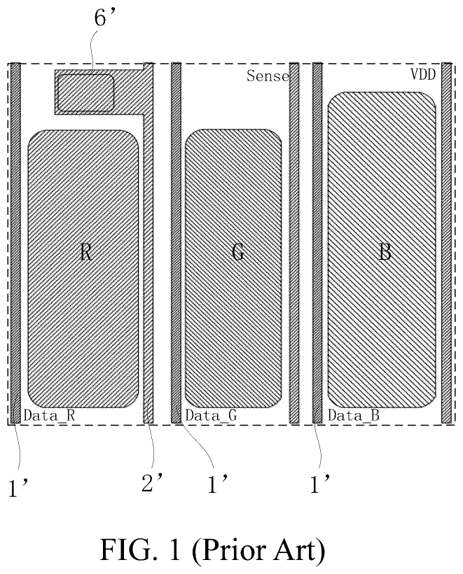

FIG. 2 is a schematic cross-sectional structural view of an exemplary display panel in the prior art.

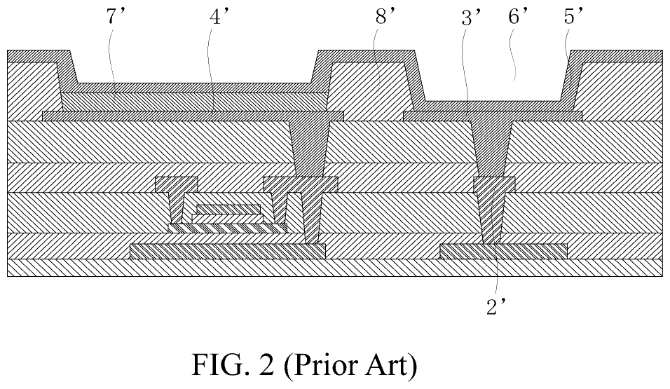

FIG. 3 is a schematic cross-sectional structural view of another exemplary display panel in the prior art.

FIG. 4 is a schematic structural view of a display panel according to an embodiment of the present disclosure.

FIG. 5 is a schematic flowchart of a manufacturing method of a display panel according to an embodiment of the present disclosure.

FIG. 6 is schematic structural views of forming a substrate and an electrode layer in the manufacturing method of a display panel according to an embodiment of the present disclosure.

FIG. 7 is a schematic structural view of forming an antioxidant metal film in the manufacturing method of a display panel according to an embodiment of the present disclosure.

FIG. 8 is a schematic structural view of forming an antioxidant metal layer in the manufacturing method of a display panel according to an embodiment of the present disclosure.

FIG. 9 is a schematic structural view of forming a pixel definition layer in the manufacturing method of a display panel according to an embodiment of the present disclosure.

FIG. 10 is a schematic structural view of forming an organic layer in the manufacturing method of a display panel according to an embodiment of the present disclosure.

### DETAILED DESCRIPTION

Technical solutions in embodiments of the present disclosure will be clearly and completely described below with reference to the accompanying drawings. Apparently, the described embodiments are merely some of embodiments of the present disclosure, not all of embodiments of the present disclosure. Based on the described embodiments in the present disclosure, all other embodiments obtained by those skilled in the art without making creative efforts belong to the scope of protection of the present disclosure.

In the description of the present disclosure, it should be understood that, orientations or positional relationships indicated by terms “center”, “longitudinal”, “transversal”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, and the like are based on orientations or positional relationships shown in the accompanying drawings, and are intended only to facilitate the description of the present disclosure and to simplify the description, not to indicate or imply that a device or an element referred to must have a particular orientation, be constructed and operated in a particular orientation, and is therefore not to be construed as limiting the present disclosure. Furthermore, terms “first” and “second” are used for descriptive purposes only and are not to be construed as indicating or implying relative importance or as implying the number of a technical feature as indicated. Thus, the feature defined by “first” and “second” maybe explicitly or implicitly defined to include one or more of the stated features. In the description of the present disclosure, “a plurality of” means two or more, unless specifically defined otherwise.

In the present disclosure, unless explicitly stated or defined otherwise, a first feature is “on” or “below” a second feature may include the first and second features being in direct contact, and may also include the first and second features not being in direct contact but being in connection via another feature between them. Moreover, a first feature is “on”, “above” and “on top of” a second feature includes that the first feature being directly above and diagonally above the second feature, or simply means that the first feature is at a higher level than the second feature. A first feature is “under”, “below” and “on bottom of” a second feature includes that the first feature being directly below and diagonally below the second feature, or simply means that the first feature is at a lower level than the second feature.

The following disclosed contents provide many different embodiments or examples for implementing different structures of the present disclosure. In order to simplify the description of the present disclosure, parts and arrangements of specific examples will be described below. Of course, they are merely exemplary and are not intended to limit the present disclosure. In addition, the present disclosure may repeatedly use reference numerals and/or reference letters in different examples, such repetition being for purposes of simplicity and clarity, and not being indicative of relationships among various embodiments and/or arrangements discussed. Furthermore, the present disclosure will provide examples of various specific processes and materials, but those skilled in the art may recognize the application of other processes and/or the use of other materials.

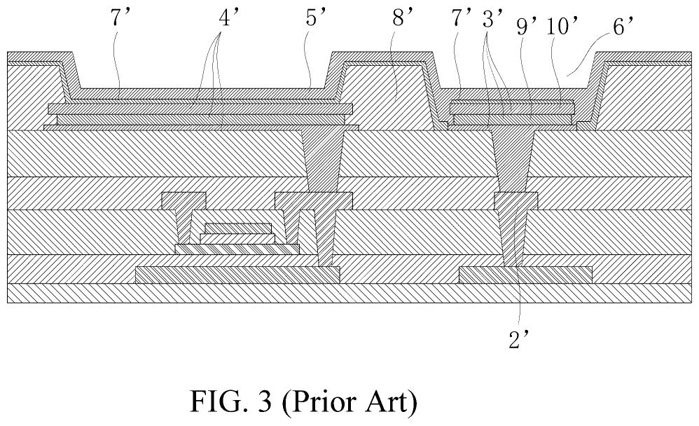

In the display panel as shown in FIG. 3, theoretically, the auxiliary electrode 3′ containing Al element can be effectively lapped with the cathode layer 5′ disposed wholly on the entire top surface, thereby effectively reducing the equivalent resistance of the cathode layer 5′ and improving the IR drop problem. However, actually, the improvement effect of IR drop is unsatisfactory. Through a transmission electron microscope (TEM) test performed on the display panel shown in FIG. 3, it was found that: according to a distribution of C element (representing an organic luminescent material) and a distribution of Ag and In elements (representing a cathode material) in the test result, the organic luminescent material was broken/fractured at the edge of the auxiliary electrode, and the cathode material was lapped with the side of the auxiliary electrode, which indicates that the cathode layer and the auxiliary electrode are directly lapped with each other on the film layer structure; however, according to a distribution of O element, the edge of the ANCL film containing Al element was oxidized, that is, there was a metal oxide between the cathode layer and the ANCL film of the auxiliary electrode. As seen from the TEM test result that, the edge of the ANCL film containing Al element was oxidized after being exposed, resulting in the increase of the direct lapping resistance between the auxiliary electrode and the cathode layer, which cannot effectively reduce the equivalent resistance of the cathode layer and thus cannot achieve the purpose of improving IR drop.

It should be noted that the equivalent resistance mentioned in the present disclosure refers to a resistance value after the cathode layer and the auxiliary electrode are connected in parallel.

In order to solve the above technical problems, the present disclosure provides an improved display panel and a manufacturing method thereof, please refer to descriptions of several embodiments in the following.

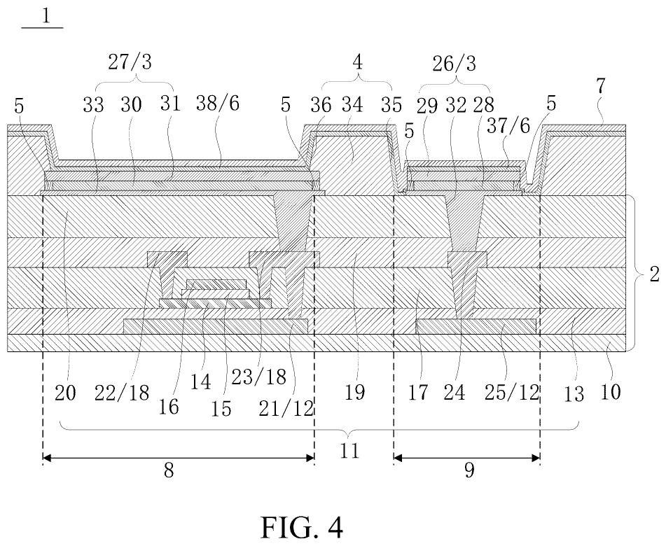

Referring to FIG. 4, an embodiment of the present disclosure provides a display panel 1. The display panel 1 includes a substrate 2, an electrode layer 3, a pixel definition layer 4, an antioxidant metal layer 5, an organic layer 6, and a cathode layer 7.

In an embodiment, the substrate 2 includes a sub-pixel region 8 and an auxiliary electrode region 9 arranged at intervals.

In an embodiment, the number of the sub-pixel region 8 is multiple (i.e., more than one), and the number of the auxiliary electrode region 9 is multiple. It may be that every other sub-pixel region 8 is disposed with one auxiliary electrode region 9 spaced therefrom, or every three sub-pixel regions 8 are disposed with one auxiliary electrode region 9 spaced therefrom, but the present disclosure is not limited to these examples. It should be noted that, the numbers and the positional relationship of the auxiliary electrode region 9 and the sub-pixel region 8 does not make a limitation in the present disclosure.

In an embodiment, the substrate 2 includes a base layer 10 and a driving circuit layer 11, and the driving circuit layer 11 is electrically connected to the electrode layer 3.

In one embodiment, the driving circuit layer 11 includes a light shielding layer 12, a buffer layer 13, an active layer 14, a gate insulating layer 15, a gate electrode layer 16, an interlayer insulating layer 17, a source-drain electrode layer 18, a passivation layer 19, and a planarization layer 20 sequentially disposed on the base layer 10 in that order. A material of the base layer 10 includes glass, but is not limited to this. The active layer 14, the gate insulating layer 15, the gate electrode layer 16, the interlayer insulating layer 17, and the source-drain electrode layer 18 form at least one thin film transistor (TFT). The light shielding layer 12 includes a first light shielding portion 21 disposed corresponding to the thin film transistor, and a material of the light shielding layer 12 is an opaque metal material. The source-drain electrode layer 18 includes a source electrode 22 and a drain electrode 23 arranged at the same layer and spaced from each other. The source electrode 22 and the drain electrode 23 are electrically connected to two ends of the active layer 14, respectively, through vias penetrating through the interlayer insulating layer 17. The drain electrode 23 is further electrically connected to the first light shielding portion 21 through a via penetrating through both the interlayer insulating layer 17 and the buffer layer 13.

In an embodiment, the driving circuit layer 11 further includes an auxiliary cathode line 24 disposed at the same layer as the source-drain electrode layer 18, and the light shielding layer 12 further includes a second light shielding portion 25 disposed corresponding to the auxiliary cathode line 24. The auxiliary cathode line 24 is electrically connected to the second light shielding portion 25 through a via penetrating through both the interlayer insulating layer 17 and the buffer layer 13.

It should be noted that, the above-mentioned specific structure of the driving circuit layer 11 is only an example, and the present disclosure does not make a limitation to the specific structure of the driving circuit layer 11.

In an embodiment, the electrode layer 3 is disposed on the substrate 2, and specifically is located on the planarization layer 20 of the substrate 2. The electrode layer 3 includes an auxiliary electrode 26 in the auxiliary electrode region 9, and an anode 27 in the sub-pixel region 8.

It can be understood that, the auxiliary electrode 26 and the anode 27 are arranged at the same layer, and have the same film structure and material.

In an embodiment, the anode 27 is electrically connected to the drain electrode 23 through a via penetrating through both the planarization layer 20 and the passivation layer 19, and the auxiliary electrode 26 is electrically connected to the auxiliary cathode line 24 through another via penetrating through both the planarization layer 20 and the passivation layer 19.

In an embodiment, the electrode layer 3 is composed of at least two electrically-conductive layers stacked one after another. In which, at least one electrically-conductive layer is a metal or alloy that contains Al element and serves as a reflective layer.

In one embodiment, the auxiliary electrode 26 includes a first auxiliary sub-electrode 28 and a second auxiliary sub-electrode 29 sequentially disposed on the substrate 2 in that order, and an edge of the second auxiliary sub-electrode 29 protrudes laterally relative to an edge of the first auxiliary sub-electrode 28. It can be understood that, the edge of the first auxiliary sub-electrode 28 is inwardly recessed with respect to the edge of the second auxiliary sub-electrode 29, so that the edge of the second auxiliary sub-electrode 29 is suspended.

In an embodiment, a material of the first auxiliary sub-electrode 28 includes a metal or alloy that contains Al element, for example ANCL alloy; and a material of the second auxiliary sub-electrode 29 includes indium tin oxide (ITO) or tungsten oxide (WOx).

In an embodiment, the wholly disposed electrode layer 3 of covering the entire top surface can be etched by selecting an appropriate etchant to form a patterned electrode layer 3, because the etchant etches the material of the first auxiliary sub-electrode 28 at a fast speed and etches the material of the second auxiliary sub-electrode 29 at a slow speed, after the etching is completed, at the edge of the formed pattern, the edge of the second auxiliary sub-electrode 29 protrudes laterally relative to the edge of the first auxiliary sub-electrode 28.

In an embodiment, the anode 27 includes a first sub-anode 30 and a second sub-anode 31 sequentially disposed on the substrate 2 in that order, and an edge of the second sub-anode 31 protrudes laterally relative to an edge of the first sub-anode 30.

In an embodiment, the first sub-anode 30 and the first auxiliary sub-electrode 28 are arranged at the same layer and made of the same material, the second sub-anode 31 and the second auxiliary sub-electrode 29 are arranged at the same layer and made of the same material.

In one embodiment, the auxiliary electrode 26 further includes a third auxiliary sub-electrode 32 arranged between the substrate 2 and the first auxiliary sub-electrode 28, and an edge of the third auxiliary sub-electrode 32 protrudes laterally relative to the edge of the first auxiliary sub-electrode 28. Correspondingly, the anode 27 further includes a third sub-anode 33 arranged between the substrate 2 and the first sub-anode 30, an edge of the third sub-anode 33 protrudes laterally relative to the edge of the first sub-anode 30, and the third sub-anode 33 and the third auxiliary sub-electrode 32 are arranged at the same layer and made of the same material.

In an embodiment, a material of the third auxiliary sub-electrode 32 includes any one of molybdenum-titanium-nickel (MoTiNi) alloy, MoTi alloy, and indium tin oxide.

It should be understood that, the edge of the first auxiliary sub-electrode 28 is inwardly recessed laterally relative to the edges of the second auxiliary sub-electrode 29 and third auxiliary sub-electrode 32, and the edge of the first sub-anode 30 is inwardly recessed laterally relative to the edges of the second sub-anode 31 and third sub-anode 33.

In an embodiment, the antioxidant metal layer 5 is bonded to the lateral side surface of the first auxiliary sub-electrode 28 and bonded to a side of the second auxiliary sub-electrode 29 facing towards the substrate 2, and an antioxidant capacity of the antioxidant metal layer 5 is greater than that of the first auxiliary sub-electrode 28.

In an embodiment, a material of the antioxidant metal layer 5 includes any one or more of titanium (Ti), silver (Ag), and molybdenum (Mo).

It can be understood that, the antioxidant metal layer 5 is disposed on the lateral side surface of the first auxiliary sub-electrode 28, which can effectively prevent the lateral side surface of the first auxiliary sub-electrode 28 from exposure, thereby effectively preventing the lateral side surface of the first auxiliary sub-electrode 28 from being oxidized. Moreover, the antioxidant capability of the antioxidant metal layer 5 is greater than that of the first auxiliary sub-electrode 28, and an exposed side surface of the antioxidant metal layer 5 is not easily oxidized.

In an embodiment, the edge of the second auxiliary sub-electrode 29 is aligned/flushed with an edge of the antioxidant metal layer 5, or the edge of the second auxiliary sub-electrode 29 protrudes laterally relative to the edge of the antioxidant metal layer 5.

In an embodiment, when forming the antioxidant metal layer 5, an antioxidant metal film may be disposed wholly to cover the entire top surface first, the antioxidant metal film covers the lateral side surface of the first auxiliary sub-electrode 28, and then the antioxidant metal film is etched by using a metal etching process. During the etching process, since the edge of the second auxiliary sub-electrode 29 protrudes laterally relative to the edge of the first auxiliary sub-electrode 28, the antioxidant metal film located on the lateral side surface of the first auxiliary sub-electrode 28 can be protected from being etched off by self-alignment effect of the second auxiliary sub-electrode 29, thereby forming the antioxidant metal layer 5 located on the lateral side surface of the first auxiliary sub-electrode 28.

It can be understood that, in the process of etching the antioxidant metal film, the second auxiliary sub-electrode 29 serves as a mask layer, which can prevent the antioxidant metal film below the second auxiliary sub-electrode 29 from being etched off.

In an embodiment, since the anode 27 has a film structure same as that of the auxiliary electrode 26, the antioxidant metal layer 5 is further bonded to the lateral side surface of the first sub-anode 30 and bonded to a side of the second sub-anode 31 facing towards the substrate 2.

In an embodiment, when the auxiliary electrode 26 includes the above-mentioned third auxiliary sub-electrode 32, and the anode 27 includes the above-mentioned third sub-anode 33, the antioxidant metal layer 5 is specifically located between the second auxiliary sub-electrode 29 and the third auxiliary sub-electrode 32, as well as between the second sub-anode 31 and the third sub-anode 33.

In an embodiment, the pixel definition layer 4 is disposed on the electrode layer 3; and the pixel definition layer 4 includes a main portion 34, and a first opening 35 and a second opening 36 both penetrating through the main portion 34. The first opening 35 is disposed corresponding to the auxiliary electrode region 9, and the second opening 36 is disposed corresponding to the sub-pixel region 8.

In an embodiment, the auxiliary electrode 26 is located in the first opening 35, a spacing between the main portion 34 and a lateral side surface of the auxiliary electrode 26 as well as the lateral side surface of the antioxidant metal layer 5 is greater than 0. The anode 27 is located in the second opening 36, and the main portion 34 at least covers the lateral side surface of the anode 27.

It can be understood that, the auxiliary electrode 26 is arranged partially covering a bottom of the first opening 35, and the anode 27 is arranged completely/fully covering a bottom of the second opening 36.

In one embodiment, a region of the substrate 2 in the first opening 35 that is not covered by the auxiliary electrode 26 is ring-shaped, that is, a spacing between any one side of the auxiliary electrode 26 and the main portion 34 is greater than 0. It can be understood that, the main portion 34 does not cover an edge position of the auxiliary electrode 26.

In an embodiment, the organic layer 6 is disposed on the substrate 2, the electrode layer 3 and the pixel definition layer 4.

In an embodiment, the organic layer 6 includes a first organic portion 37 on the second auxiliary sub-electrode 29, and a second organic portion 38 spaced from the first organic portion 37 and located on the lateral side of the auxiliary electrode 26. The second organic portion 38 extends from the substrate 2 in the auxiliary electrode region 9 to the main portion 34 of the pixel definition layer 4 and the second sub-anode 31.

In an embodiment, a thickness of the organic layer 6 is less than a thickness of the first auxiliary sub-electrode 28.

It can be understood that, the organic layer 6 is naturally broken/fractured at the edge of the second auxiliary sub-electrode 29 to form the first organic portion 37 and the second organic portion 38 spaced from each other. Since the thickness of the organic layer 6 is less than the thickness of the first auxiliary sub-electrode 28, the broken/fractured position of the organic layer 6 would expose the lateral side surface of the second auxiliary sub-electrode 29 and expose at least some of the lateral side surface of the antioxidant metal layer 5.

In an embodiment, when the auxiliary electrode 26 includes the above-mentioned third auxiliary sub-electrode 32, the second organic portion 38 at least covers the lateral side surface of the third auxiliary sub-electrode 32, but does not completely cover the lateral side surface of the antioxidant metal layer 5.

In an embodiment, the organic layer 6 maybe a whole organic light-emitting functional layer, or a partial organic light-emitting functional layer. When the organic layer 6 is the whole organic light-emitting functional layer, the organic layer 6 includes a hole injection layer, a hole transport layer, a light-emitting layer, an electron transport layer, and an electron injection layer sequentially stacked in that order. When the organic layer 6 is the partial organic light-emitting functional layer, the organic layer 6 includes an electron transport layer and an electron injection layer sequentially stacked in that order; and in this case, a hole injection layer, a hole transport layer, and a light-emitting layer are only stacked in the sub-pixel region 8, specifically between the organic layer 6 and the anode 27. It should be noted that, the present disclosure does not make a limitation to the specific composition of the organic layer 6.

In an embodiment, the cathode layer 7 is arranged on the first organic portion 37 and the second organic portion 38, and is electrically connected to the lateral side surface of the second auxiliary sub-electrode 29 as well as the lateral side surface of the antioxidant metal layer 5.

It can be understood that, the cathode layer 7 is disposed wholly over the entire top surface, and the cathode layer 7 is directly lapped with the lateral side surface of the second auxiliary sub-electrode 29 as well as the lateral side surface of the antioxidant metal layer 5 at the broken position of the organic layer 6.

In an embodiment, the cathode layer 7 is directly lapped with the lateral side surface of the antioxidant metal layer 5, so as to realize an electrical connection with the first auxiliary sub-electrode 28.

In an embodiment, the cathode layer 7 is electrically connected to the auxiliary electrode 26 for the purpose of reducing the equivalent resistance of the cathode layer 7 by parallel connection, thereby improving the IR drop effect of the display panel 1. In the embodiments of the present disclosure, the antioxidant metal layer 5 with a stronger antioxidant capacity is formed on the lateral side surface of the first auxiliary sub-electrode 28 containing Al element, which can prevent the lateral side surface of the first auxiliary sub-electrode 28 from being oxidized, so that the cathode layer 7 is effectively lapped with the auxiliary electrode 26 through the antioxidant metal layer 5, avoiding an increase of lapping resistance between the cathode layer 7 and the auxiliary electrode 26 due to the lateral side surface of the auxiliary electrode 26 being oxidized.

Accordingly, in the embodiments of the present disclosure, the lateral side surface of the first auxiliary sub-electrode 28 is formed with the antioxidant metal layer 5, which can effectively protect the lateral side surface of the first auxiliary sub-electrode 28 and prevent the lateral side surface of the first auxiliary sub-electrode 28 from exposure and thus being oxidized, so that the cathode layer 7 can be directly lapped with the lateral side surface of the antioxidant metal layer 5 and the lateral side surface of the second auxiliary sub-electrode 29 when being formed. That is, the cathode layer 7 and the lateral side surface of the auxiliary electrode 26 form an effective lapping, thereby preventing the lapping resistance between the cathode layer 7 and the auxiliary electrode 26 from being increased due to the lateral side surface of the auxiliary electrode 26 being oxidized, and thus ensuring the improvement effect of IR drop for the display panel 1.

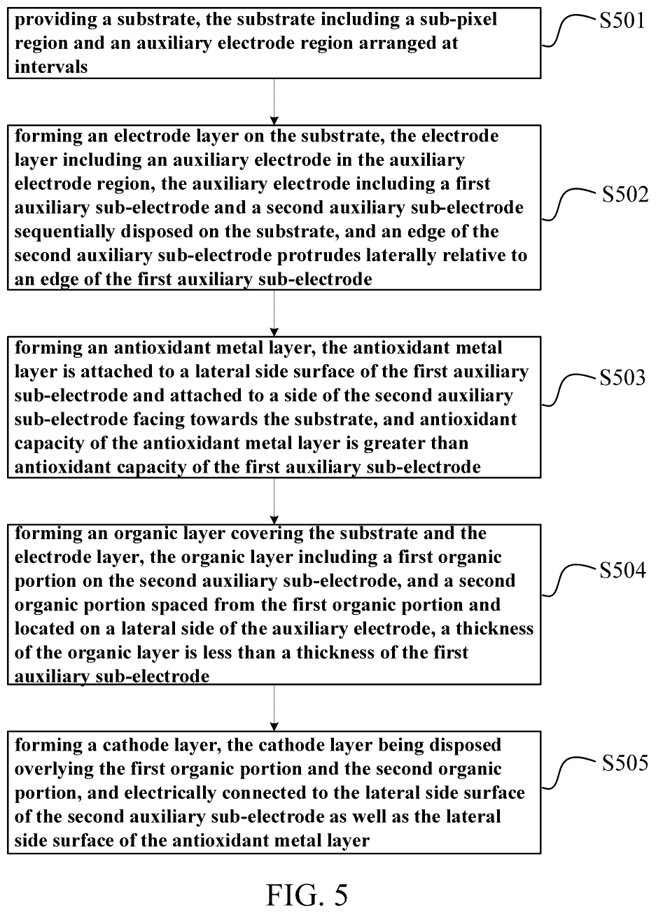

Referring to FIG. 4 through FIG. 10, an embodiment of the present disclosure provides a manufacturing method used for manufacturing the display panel 1 described in the above-mentioned embodiments. The manufacturing method includes steps S501 to S505.

S501: providing a substrate. The substrate includes a sub-pixel region and an auxiliary electrode region arranged at intervals.

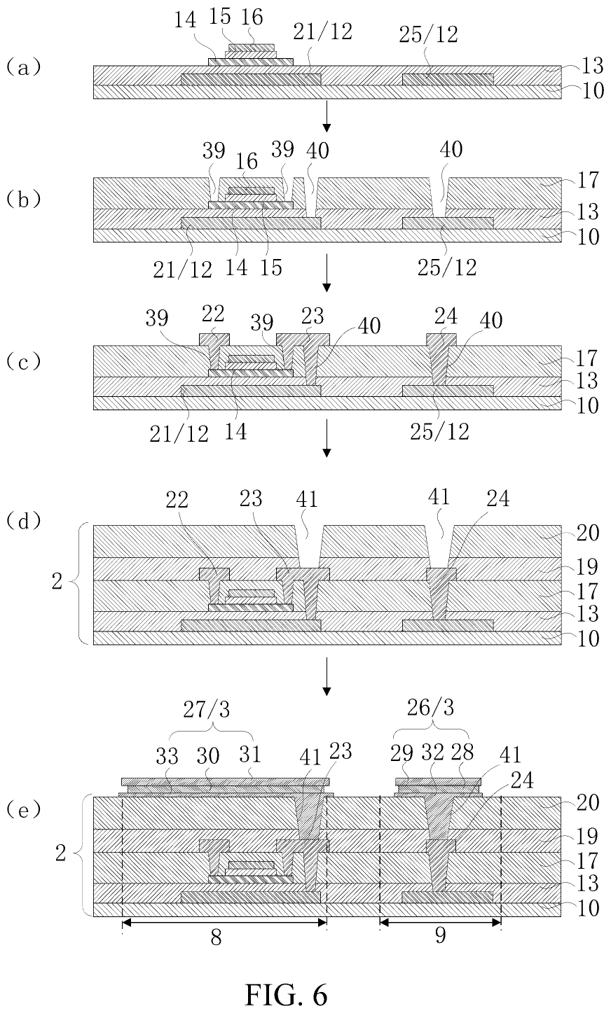

As illustrated in (e) of FIG. 6, the substrate 2 includes the sub-pixel region 8 and the auxiliary electrode region 9 arranged at intervals.

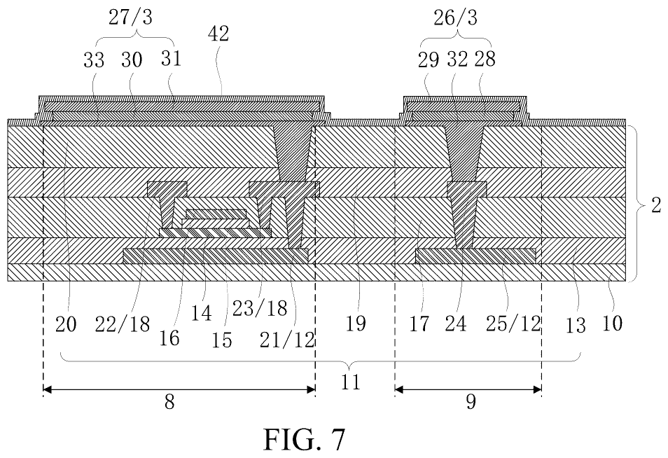

As illustrated in FIG. 7, the substrate 2 includes a base layer 10 and a driving circuit layer 11 disposed on the base layer 10.

In an embodiment, as shown in FIG. 7, the driving circuit layer 11 includes a light shielding layer 12, a buffer layer 13, an active layer 14, a gate insulating layer 15, a gate electrode layer 16, an interlayer insulating layer 17, a source-drain electrode layer 18, a passivation layer 19, and a planarization layer 20 sequentially arranged on the base layer 10. The active layer 14, the gate insulating layer 15, the gate electrode layer 16, the interlayer insulating layer 17, and the source-drain electrode layer 18 form at least one thin film transistor. The light shielding layer 12 includes a first light shielding portion 21 disposed corresponding to the thin film transistor, and a material of the light shielding layer 12 is an opaque metal material. The source-drain electrode layer 18 includes a source electrode 22 and a drain electrode 23 arranged at the same layer and spaced from each other. The source electrode 22 and the drain electrode 23 are electrically connected to two ends of the active layer 14 respectively through vias penetrating through the interlayer insulating layer 17. The drain electrode 23 is further electrically connected to the first light shielding portion 21 through a via penetrating through both the interlayer insulating layer 17 and the buffer layer 13.

In an embodiment, the driving circuit layer 11 further includes an auxiliary cathode line arranged at the same layer as the source-drain electrode layer 18, and the light shielding layer 12 further includes a second light shielding portion 25 disposed corresponding to the auxiliary cathode line 24. The auxiliary cathode line 24 is electrically connected to the second light shielding portion 25 through a via penetrating through both the interlayer insulating layer 17 and the buffer layer 13.

In an embodiment, as shown in FIG. 6, a manufacturing step of the substrate 2 includes sub-steps as follows.

As illustrated in (a) of FIG. 6, the light shielding layer 12, the buffer layer 13, the active layer 14, the gate insulating layer 15, and the gate electrode layer 16 are sequentially formed on the base layer 10 in that order. The light shielding layer 13 includes the first light shielding portion 21 and the second light shielding portion 25 spaced from each other. The first light shielding portion 21 is disposed corresponding to the active layer 14 and the gate electrode layer 16.

As illustrated in (b) of FIG. 6, the interlayer insulating layer 17 covering the buffer layer 13, the active layer 14, the gate insulating layer 15 and the gate electrode layer 16 is formed, two first vias 39 penetrating through the interlayer insulating layer 17 and disposed corresponding to two ends of the active layer 14 respectively are formed, and two second vias 40 penetrating through both the interlayer insulating layer 17 and the buffer layer 13 and disposed corresponding to the first light shielding portion 21 and the second light shielding portion 25 respectively are formed.

As illustrated in (c) of FIG. 6, the source electrode 22, the drain electrode 23, and the auxiliary cathode line 24 are formed on the interlayer insulating layer 17. The source electrode 22 and the drain electrode 23 are electrically connected to the two ends of the active layer 14 through the two first vias 39, respectively. The drain electrode 23 is further electrically connected to the first light shielding portion 21 through one of the second vias 40, and the auxiliary cathode line 24 is electrically connected to the second light shielding portion 25 through the other one of the second vias 40.

As illustrated in (d) of FIG. 6, the passivation layer 19 and the planarization layer 20 covering the source electrode 22, the drain electrode 23 and the auxiliary cathode line 24 are sequentially formed, and two third vias 41 penetrating through both the passivation layer 19 and the planarization layer 20 and disposed corresponding to the drain electrode 23 and the auxiliary cathode line 24 respectively are formed.

S502: forming an electrode layer on the substrate. The electrode layer includes an auxiliary electrode in the auxiliary electrode region. The auxiliary electrode includes a first auxiliary sub-electrode and a second auxiliary sub-electrode sequentially disposed on the substrate, and an edge of the second auxiliary sub-electrode protrudes laterally relative to an edge of the first auxiliary sub-electrode.

As illustrated in (e) of FIG. 6, the electrode layer 3 is formed on the planarization layer 20 of the substrate 2. The electrode layer 3 includes the auxiliary electrode 26 in the auxiliary electrode region 9 and an anode 27 in the sub-pixel region 8. The anode 27 is electrically connected to the drain electrode 23 through one of the third vias 41, and the auxiliary electrode 26 is electrically connected to the auxiliary cathode line 24 through the other one of the third vias 41.

In an embodiment, the auxiliary electrode 26 includes the first auxiliary sub-electrode 28 and the second auxiliary sub-electrode 29 sequentially arranged on the substrate 2 in that order, and the edge of the second auxiliary sub-electrode 29 protrudes laterally relative to the edge of the first auxiliary sub-electrode 28. In other embodiments, the auxiliary electrode 26 further includes a third auxiliary sub-electrode 32 located between the substrate 2 and the first auxiliary sub-electrode 28, and an edge of the third auxiliary sub-electrode 32 protrudes laterally relative to the edge of the first auxiliary sub-electrode 28.

In an embodiment, a material of the first auxiliary sub-electrode 28 includes a metal or alloy that contains Al element, for example, ANCL alloy; a material of the second auxiliary sub-electrode 29 includes ITO or WOx; and a material of the third auxiliary sub-electrode 32 includes any one of MoTiNi alloy, MoTi alloy and ITO.

In an embodiment, the anode 27 includes a first sub-anode 30 and a second sub-anode 31 sequentially disposed on the substrate 2 in that order, and an edge of the second sub-anode 31 protrudes laterally relative to an edge of the first sub-anode 30. The first sub-anode 30 and the first auxiliary sub-electrode 28 are arranged at the same layer and are made of the same material, and the second sub-anode 31 and the second auxiliary sub-electrode 29 are arranged at the same layer and are made of the same material. In other embodiments, the anode 27 further includes a third sub-anode 33 located between the substrate 2 and the first sub-anode 30, an edge of the third sub-anode 33 protrudes laterally relative to the edge of the first sub-anode 30, and the third sub-anode 33 and the third auxiliary sub-electrode 32 are arranged at the same layer and made of the same material.

In an embodiment, the wholly disposed electrode layer of covering the entire top surface can be etched by selecting an appropriate etchant to form the patterned electrode layer 3, because the etchant etches the material of first auxiliary sub-electrode (the material of first sub-anode) at a high speed and etches the material of second auxiliary sub-electrode (the material of second sub-anode) and the material of third auxiliary sub-electrode (the material of third sub-anode) at a low speed, and therefore, after the etching is completed, at the edge of the formed pattern, the edge of the second auxiliary sub-electrode 29 protrudes laterally relative to the edge of the first auxiliary sub-electrode 28, the edge of the third auxiliary sub-electrode 32 protrudes laterally relative to the edge of the first auxiliary sub-electrode 28, and meanwhile, the edge of the second sub-anode 31 protrudes laterally relative to the edge of the first sub-anode 30, and the edge of the third sub-anode 33 protrudes laterally relative to the edge of the first sub-anode 30.

S503, forming an antioxidant metal layer. The antioxidant metal layer is bonded to a lateral side surface of the first auxiliary sub-electrode and bonded to a side of the second auxiliary sub-electrode facing towards the substrate, and an antioxidant capacity of the antioxidant metal layer is greater than an antioxidant capacity of the first auxiliary sub-electrode.

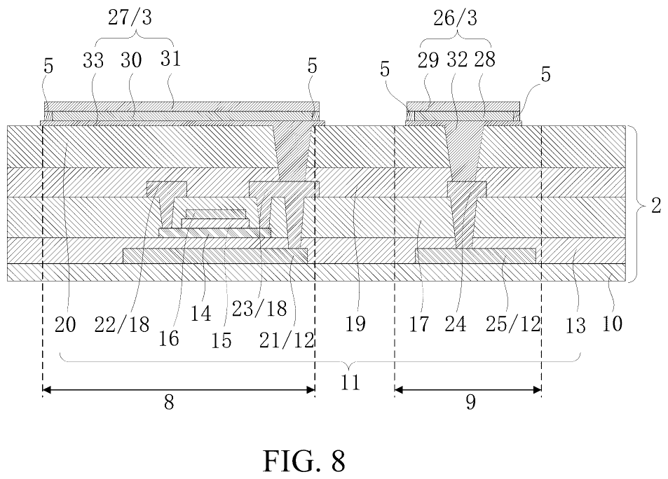

In an embodiment, as illustrated in FIG. 8, the antioxidant metal layer 5 is bonded to the lateral side surface of the first auxiliary sub-electrode 28 and bonded to a side of the second auxiliary sub-electrode 29 facing towards the substrate 2, and meanwhile, the antioxidant metal layer 5 is further bonded to the lateral side surface of the first sub-anode 30 and bonded to a side of the second sub-anode 31 facing towards the substrate 2. When the auxiliary electrode 26 includes the above-mentioned third auxiliary sub-electrode 32 and the anode 27 includes the above-mentioned third sub-anode 33, the antioxidant metal layer 5 is specifically located between the second auxiliary sub-electrode 29 and the third auxiliary sub-electrode 32, as well as between the second sub-anode 31 and the third sub-anode 33.

In an embodiment, a material of the antioxidant metal layer 5 includes any one or more of Ti, Ag and Mo.

In an embodiment, the step S503 includes sub-steps as follows.

As illustrated in FIG. 7, the substrate 2 formed with the electrode layer 3 is wholly covered with an antioxidant metal film 42. The antioxidant metal film 42 is further disposed covering the lateral side surface of the first auxiliary electrode 28.

As illustrated in FIG. 8, the antioxidant metal film 42 is etched wholly by a metal etching process to form the antioxidant metal layer 5 located on the side of the second auxiliary sub-electrode 29 facing towards the substrate 2 and on the side of the second sub-anode 31 facing towards the substrate 2.

As shown in FIG. 7 and FIG. 8, in the etching process, since the edge of the second auxiliary sub-electrode 29 protrudes laterally relative to the edge of the first auxiliary sub-electrode 28, the antioxidant metal film 42 on the lateral side surface of the first auxiliary sub-electrode 28 can be protected from being etched off by using self-alignment effect of the second auxiliary sub-electrode 29, so that the antioxidant metal layer 5 on the lateral side surface of the first auxiliary sub-electrode 28 is formed. Likewise, since the edge of the second sub-anode 31 protrudes laterally relative to the edge of the first sub-anode 30, the antioxidant metal film 42 on the lateral side surface of the first sub-anode 30 can be protected from being etched off by using self-alignment effect of the second sub-anode 31, so that the antioxidant metal layer 5 on the lateral side surface of the first sub-anode 30 is formed.

It can be understood that, in the process of etching the antioxidant metal film 42, the second auxiliary sub-electrode 29 and the second sub-anode 31 serve as mask layers, which can prevent the antioxidant metal film 42 just below the second auxiliary sub-electrode 29 and the second sub-anode 31 from being etched off.

In an embodiment, the edge of the second auxiliary sub-electrode 29 is aligned/flushed with the edge of the antioxidant metal layer 5, or the edge of the second auxiliary sub-electrode 29 protrudes laterally relative to the edge of the antioxidant metal layer 5. Likewise, the edge of the second sub-anode 31 is aligned/flushed with the edge of the antioxidant metal layer 5, or the edge of the second sub-anode 31 protrudes laterally relative to the edge of the antioxidant metal layer 5.

S504: forming an organic layer covering the substrate and the electrode layer. The organic layer includes a first organic portion on the second auxiliary sub-electrode, and a second organic portion spaced from the first organic portion and located on a lateral side of the auxiliary electrode. A thickness of the organic layer is less than a thickness of the first auxiliary sub-electrode.

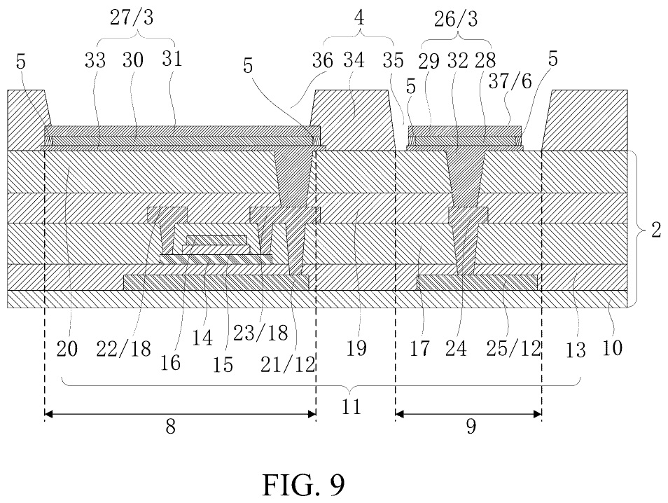

In an embodiment, as illustrated in FIG. 9, before forming the organic layer, a pixel definition layer 4 is needed to be formed.

In an embodiment, the pixel definition layer 4 includes a main portion 34, and a first opening 35 and a second opening 36 both penetrating through the main portion 34. The first opening 35 is disposed corresponding to the auxiliary electrode region 9, and the second opening 36 is disposed corresponding to the sub-pixel region 8.

In an embodiment, the auxiliary electrode 26 is located in the first opening 35, a spacing between the main portion 34 and the lateral side surface of the auxiliary electrode 26 as well as the lateral side surface of the antioxidant metal layer 5 is greater than 0, the anode 27 is located in the second opening 36, and the main portion 34 at least covers the lateral side surface of the anode 27.

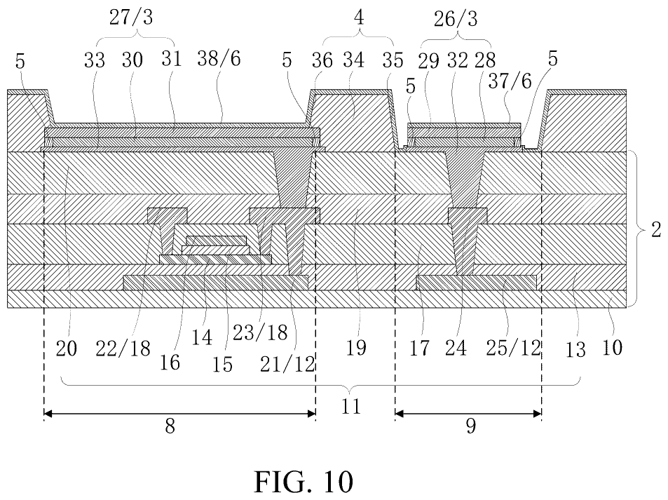

In an embodiment, as illustrated in FIG. 10, after the pixel definition layer 4 is formed, the organic layer 6 is disposed wholly. Since the thickness of the organic layer 6 is less than the thickness of the first auxiliary sub-electrode 28, the thickness of the organic layer 6 is much less than that of the auxiliary electrode 26, so that the organic layer 6 is naturally broken/fractured at the edge of the second auxiliary sub-electrode 29 to form a first organic portion 37 and a second organic portion 38 spaced apart from each other, and the broken/fractured position of the organic layer 6 exposes the lateral side surface of the second auxiliary sub-electrode 29 and at least some of the lateral side surface of the antioxidant metal layer 5.

In an embodiment, the first organic portion 37 is disposed overlying/covering the second auxiliary sub-electrode 29, and the second organic portion 38 is disposed overlying/covering the anode electrode 27, the main portion 34 of the pixel definition layer 4, and the planarization layer 20 of the substrate 2.

When the auxiliary electrode 26 includes the above-mentioned third auxiliary sub-electrode 32, the second organic portion 38 at least covers the lateral side surface of the third auxiliary sub-electrode 32, but does not completely cover the lateral side surface of the antioxidant metal layer 5.

In an embodiment, the organic layer 6 maybe a whole organic light-emitting functional layer, or a partial organic light-emitting functional layer. When the organic layer 6 is the whole organic light-emitting functional layer, the organic layer 6 includes a hole injection layer, a hole transport layer, a light-emitting layer, an electron transport layer, and an electron injection layer sequentially stacked in that order. When the organic layer 6 is the partial organic light-emitting functional layer, the organic layer 6 includes an electron transport layer and an electron injection layer sequentially stacked in that order; and in this case, a hole injection layer, a hole transport layer, and a light-emitting layer are only stacked in the sub-pixel region 8, specifically between the organic layer 6 and the anode 27. It should be noted that, the present disclosure does not make a limitation to the specific composition of the organic layer 6.

S505: forming a cathode layer. The cathode layer is disposed overlying/covering the first organic portion and the second organic portion, and electrically connected to the lateral side surface of the second auxiliary sub-electrode as well as the lateral side surface of the antioxidant metal layer.

As illustrated in FIG. 4, the cathode layer 7 is disposed wholly for covering the entire top surface, for example, formed by evaporation or sputtering. Specifically, the cathode layer 7 is located on the first organic portion 37 and the second organic portion 38, and is electrically connected to the lateral side surface of the second auxiliary sub-electrode 29 and the lateral side surface of the antioxidant metal layer 5.

It can be understood that, the cathode layer 7 is directly lapped with the lateral side surface of the second auxiliary sub-electrode 29 as well as the lateral side surface of the antioxidant metal layer 5 at the broken position of the organic layer 6.

In an embodiment, the cathode layer 7 is directly lapped with the lateral side surface of the antioxidant metal layer 5, so as to realize an electrical connection with the first auxiliary sub-electrode 28.

In the embodiments of the present disclosure, the lateral side surface of the first auxiliary sub-electrode 28 is formed with the antioxidant metal layer 5, which can effectively protect the lateral side surface of the first auxiliary sub-electrode 28 and prevent the lateral side surface of the first auxiliary sub-electrode 28 from exposure and thus being oxidized, so that the cathode layer 7 can be directly lapped with the lateral side surface of the antioxidant metal layer 5 and the lateral side surface of the second auxiliary sub-electrode 29 when being formed. That is, the cathode layer 7 and the lateral side surface of the auxiliary electrode 26 form an effective lapping, thereby preventing the lapping resistance between the cathode layer 7 and the auxiliary electrode 26 from being increased due to the side surface of the auxiliary electrode 26 being oxidized, and thus ensuring the improvement effect of IR drop for the display panel 1.

In the above embodiments, the descriptions of various embodiments have their own emphases, and for a part of a certain embodiment that is not described in detail, reference may be made to the description of other embodiments.

The foregoing provides a detailed description to the display panel and the manufacturing method thereof according to embodiments of the present disclosure, and in this specification, specific examples are used to describe the principles and embodiments of the present disclosure, and the description of the above embodiments is only used to help understand the technical solutions and the core idea of the present disclosure. Those skilled in the art should understand that, the technical solutions described in the foregoing embodiments can still be modified, or some of the technical features thereof can be equivalently replaced, and such modifications or replacements do not cause the essence of the corresponding technical solutions to deviate from the scope of the technical solutions of the embodiments of the present disclosure.

What is claimed is:

1. A display panel, comprising:
a substrate, comprising a sub-pixel region and an auxiliary electrode region arranged at intervals;
an electrode layer, disposed on the substrate and comprising an auxiliary electrode located in the auxiliary electrode region, wherein the auxiliary electrode comprises a first auxiliary sub-electrode and a second auxiliary sub-electrode sequentially arranged on the substrate, and an edge of the second auxiliary sub-electrode protrudes laterally relative to an edge of the first auxiliary sub-electrode;
an antioxidant metal layer, bonded to a side surface of the first auxiliary sub-electrode and bonded to a side of the second auxiliary sub-electrode facing towards the substrate, wherein an antioxidant capacity of the antioxidant metal layer is greater than an antioxidant capacity of the first auxiliary sub-electrode;
an organic layer, disposed on the substrate and the electrode layer, and comprising a first organic portion on the second auxiliary sub-electrode, and a second organic portion spaced from the first organic portion and on a side of the auxiliary electrode; wherein a thickness of the organic layer is less than a thickness of the first auxiliary sub-electrode; and
a cathode layer, disposed on the first organic portion and the second organic portion, and electrically connected to a side surface of the second auxiliary sub-electrode and a side surface of the antioxidant metal layer.

2. The display panel according to claim 1, wherein the edge of the second auxiliary sub-electrode is aligned with an edge of the antioxidant metal layer, or the edge of the second auxiliary sub-electrode protrudes laterally relative to the edge of the antioxidant metal layer.

3. The display panel according to claim 1, wherein a material of the antioxidant metal layer comprises one or more of titanium, silver and molybdenum.

4. The display panel according to claim 1, wherein a material of the first auxiliary sub-electrode comprises a metal or alloy that contains aluminum element, and a material of the second auxiliary sub-electrode comprises indium tin oxide or a tungsten oxide.

5. The display panel according to claim 1, wherein the auxiliary electrode further comprises a third auxiliary sub-electrode located between the substrate and the first auxiliary sub-electrode, an edge of the third auxiliary sub-electrode protrudes laterally relative to the edge of the first auxiliary sub-electrode, the antioxidant metal layer is arranged between the second auxiliary sub-electrode and the third auxiliary sub-electrode, and the second organic portion at least covers a side surface of the third auxiliary sub-electrode.

6. The display panel according to claim 5, wherein a material of the third auxiliary sub-electrode comprises any one of molybdenum-titanium-nickel (MoTiNi) alloy, molybdenum-titanium (MoTi) alloy, and indium tin oxide.

7. The display panel according to claim 1, wherein the electrode layer further comprises an anode located in the sub-pixel region; the anode comprises a first sub-anode and a second sub-anode sequentially disposed on the substrate; and an edge of the second sub-anode protrudes laterally relative to an edge of the first sub-anode;
wherein the first sub-anode and the first auxiliary sub-electrode are arranged at a same layer and are made of a same material, the second sub-anode and the second auxiliary sub-electrode are arranged at a same layer and are made of a same material, and the second organic portion extends onto the second sub-anode;
wherein the antioxidant metal layer is bonded to a side surface of the first sub-anode and bonded to a side of the second sub-anode facing towards the substrate.

8. The display panel according to claim 7, wherein the display panel further comprises a pixel definition layer disposed on the electrode layer, and the organic layer and the cathode layer are sequentially disposed overlying the pixel definition layer; the pixel definition layer comprises a main portion, and a first opening and a second opening penetrating through the main portion; the first opening is disposed corresponding to the auxiliary electrode region, and the second opening is disposed corresponding to the sub-pixel region;
wherein the auxiliary electrode is located in the first opening, a spacing between the main portion and a side surface of the auxiliary electrode as well as the side surface of the antioxidant metal layer is greater than 0, the anode is located in the second opening, and the main portion at least covers a side surface of the anode.

9. A manufacturing method of a display panel, comprising the following steps:
providing a substrate, wherein the substrate comprises a sub-pixel region and an auxiliary electrode region arranged at intervals;
forming an electrode layer on the substrate, wherein the electrode layer comprises an auxiliary electrode located in the auxiliary electrode region, the auxiliary electrode comprises a first auxiliary sub-electrode and a second auxiliary sub-electrode sequentially disposed on the substrate, and an edge of the second auxiliary sub-electrode protrudes laterally relative to an edge of the first auxiliary sub-electrode;
forming an antioxidant metal layer, wherein the antioxidant metal layer is bonded to a side surface of the first auxiliary sub-electrode and bonded to a side of the second auxiliary sub-electrode facing towards the substrate, and an antioxidant capacity of the antioxidant metal layer is greater than an antioxidant capacity of the first auxiliary sub-electrode;
forming an organic layer covering the substrate and the electrode layer, wherein the organic layer comprises a first organic portion on the second auxiliary sub-electrode, and a second organic portion spaced from the first organic portion and disposed on the substrate; and a thickness of the organic layer is less than a thickness of the first auxiliary sub-electrode; and
forming a cathode layer, wherein the cathode layer is disposed overlying the first organic portion and the second organic portion, and electrically connected to a side surface of the second auxiliary sub-electrode and a side surface of the antioxidant metal layer.

10. The manufacturing method of the display panel according to claim 9, wherein the step of forming an antioxidant metal layer comprises:
covering with an antioxidant metal film wholly on the substrate formed with the electrode layer, wherein the antioxidant metal film covers the side surface of the first auxiliary sub-electrode; and
etching the antioxidant metal film wholly to form the antioxidant metal layer located on a side of the second auxiliary sub-electrode facing towards the substrate.

11. The manufacturing method according to claim 9, wherein the edge of the second auxiliary sub-electrode is aligned with an edge of the antioxidant metal layer, or the edge of the second auxiliary sub-electrode protrudes laterally relative to the edge of the antioxidant metal layer.

12. The manufacturing method according to claim 9, wherein a material of the antioxidant metal layer comprises one or more of titanium, silver and molybdenum.

13. The manufacturing method according to claim 9, wherein a material of the first auxiliary sub-electrode comprises a metal or alloy that contains aluminum element, and a material of the second auxiliary sub-electrode

14. The manufacturing method according to claim 9, wherein the auxiliary electrode further comprises a third auxiliary sub-electrode located between the substrate and the first auxiliary sub-electrode, an edge of the third auxiliary sub-electrode protrudes laterally relative to the edge of the first auxiliary sub-electrode, the antioxidant metal layer is arranged between the second auxiliary sub-electrode and the third auxiliary sub-electrode, and the second organic portion at least covers a side surface of the third auxiliary sub-electrode.

15. A display panel, comprising:
a substrate, comprising a sub-pixel region and an auxiliary electrode region arranged at intervals;
an electrode layer, disposed on the substrate and comprising an auxiliary electrode located in the auxiliary electrode region, wherein the auxiliary electrode comprises a first auxiliary sub-electrode and a second auxiliary sub-electrode sequentially arranged on the substrate, and an edge of the second auxiliary sub-electrode protrudes laterally relative to an edge of the first auxiliary sub-electrode;
an antioxidant metal layer, bonded to a side surface of the first auxiliary sub-electrode and bonded to a side of the second auxiliary sub-electrode facing towards the substrate, wherein an antioxidant capacity of the antioxidant metal layer is greater than an antioxidant capacity of the first auxiliary sub-electrode;
an organic layer, disposed on the substrate and the electrode layer, and comprising a first organic portion on the second auxiliary sub-electrode, and a second organic portion spaced from the first organic portion and on a side of the auxiliary electrode; wherein a thickness of the organic layer is less than a thickness of the first auxiliary sub-electrode; and
a cathode layer, disposed on the first organic portion and the second organic portion, and electrically connected to a side surface of the second auxiliary sub-electrode and a side surface of the antioxidant metal layer;
wherein the edge of the second auxiliary sub-electrode is aligned with an edge of the antioxidant metal layer, or the edge of the second auxiliary sub-electrode protrudes laterally relative to the edge of the antioxidant metal layer;
wherein the auxiliary electrode further comprises a third auxiliary sub-electrode located between the substrate and the first auxiliary sub-electrode, an edge of the third auxiliary sub-electrode protrudes laterally relative to the edge of the first auxiliary sub-electrode, the antioxidant metal layer is arranged between the second auxiliary sub-electrode and the third auxiliary sub-electrode, and the second organic portion at least covers a side surface of the third auxiliary sub-electrode.

16. The display panel according to claim 15, wherein a material of the antioxidant metal layer comprises one or more of titanium, silver and molybdenum.

17. The display panel according to claim 15, wherein a material of the first auxiliary sub-electrode comprises a metal or alloy that contains aluminum element, and a material of the second auxiliary sub-electrode comprises indium tin oxide or a tungsten oxide.

18. The display panel according to claim 15, wherein a material of the third auxiliary sub-electrode comprises any one of molybdenum-titanium-nickel (MoTiNi) alloy, molybdenum-titanium (MoTi) alloy, and indium tin oxide.

19. The display panel according to claim 15, wherein the electrode layer further comprises an anode located in the sub-pixel region; the anode comprises a first sub-anode and a second sub-anode sequentially disposed on the substrate; and an edge of the second sub-anode protrudes laterally relative to an edge of the first sub-anode;
wherein the first sub-anode and the first auxiliary sub-electrode are arranged at a same layer and are made of a same material, the second sub-anode and the second auxiliary sub-electrode are arranged at a same layer and are made of a same material, and the second organic portion extends onto the second sub-anode;
wherein the antioxidant metal layer is bonded to a side surface of the first sub-anode and bonded to a side of the second sub-anode facing towards the substrate.

20. The display panel according to claim 19, wherein the display panel further comprises a pixel definition layer disposed on the electrode layer, and the organic layer and the cathode layer are sequentially disposed overlying the pixel definition layer; the pixel definition layer comprises a main portion, and a first opening and a second opening penetrating through the main portion; the first opening is disposed corresponding to the auxiliary electrode region, and the second opening is disposed corresponding to the sub-pixel region;
wherein the auxiliary electrode is located in the first opening, a spacing between the main portion and a side surface of the auxiliary electrode as well as the side surface of the antioxidant metal layer is greater than 0, the anode is located in the second opening, and the main portion at least covers a side surface of the anode.
